(19) United States
(12) Patent Application Publication
(10) Pub. No.: US 2022/0068723 A1
(43) Pub. Date: Mar. 3, 2022

(54) METHOD FOR FORMING A SEMICONDUCTOR DEVICE

(71) Applicant: United Semiconductor (Xiamen) Co., Ltd., Xiamen (CN)

(72) Inventors: TAO HU, Shamen City (CN); Xiao Dong Shi, Shamen City (CN); JINJIAN OUYANG, Xiamen (CN); WEN YI TAN, Xiamen (CN)

(21) Appl. No.: 17/026,319

(22) Filed: Sep. 21, 2020

(30) Foreign Application Priority Data
Aug. 28, 2020 (CN) 202010883406.4

(51) Int. Cl. H01L 21/8238; H01L 29/66

(52) U.S. Cl. CPC H01L 21/823807; H01L 29/7847; H01L 29/665

(57) ABSTRACT

A method for forming a semiconductor device is disclosed. A semiconductor substrate having thereon an NMOS region, a PMOS region, and a non-silicide region is provided. An NMOS transistor is formed within the NMOS region and a PMOS transistor is formed within the PMOS region. A stress memorization technique (SMT) layer covering the NMOS region, the PMOS region, and the non-silicide region is formed. The SMT layer is removed from the PMOS region. A stress is transferred from the SMT layer into an N-channel of the NMOS transistor. The SMT layer is removed from the NMOS region, while leaving the SMT layer in the non-silicide region intact. A self-aligned silicidation (SAC) process is performed to form a salicide layer in the NMOS region and the PMOS region.

### BACKGROUND OF THE INVENTION

### 1. Field of the Invention

The present invention relates generally to the field of semiconductor manufacturing technology, and particularly relates to a method of manufacturing a semiconductor device.

### 2. Description of the Prior Art

It is known that Stress Memorization Technology (SMT) is usually performed after the source/drain (S/D) ion implantation step in the semiconductor process to induce stress on the channel area of a metal-oxide-semiconductor field effect transistor (MOSFET).

In the conventional SMT process, a stress layer and laser annealing are usually used to induce stress in the substrate, that is, the polysilicon gate under the stress layer is recrystallized by laser annealing to improve the electrical properties of the N-channel MOSFET (NMOSFET, hereinafter referred to as NMOS). The aforementioned stress layer is removed before the subsequent self-aligned silicidation process.

During the self-aligned metal silicide process, it is necessary to deposit a salicide block (SAB) layer, such as a silicon oxide layer and a silicon nitride layer. Exposure and development processes are performed to pattern the SAB layer to mask the area where the silicide layer is not needed (non-silicide region). However, the above-mentioned SMT process and self-aligned metal silicide process require multiple depositions and etchings, and the steps are relatively complicated.

### SUMMARY OF THE INVENTION

It is one object of the present invention to provide an improved semiconductor manufacturing process that can simplify the process steps to solve the deficiencies and shortcomings of the prior art.

According to one aspect of the invention, a method for forming a semiconductor device is disclosed. A semiconductor substrate having thereon an NMOS region, a PMOS region, and a non-silicide region is provided. An NMOS transistor is formed within the NMOS region and a PMOS transistor is formed within the PMOS region. A stress memorization technique (SMT) layer covering the NMOS region, the PMOS region, and the non-silicide region is formed. The SMT layer is removed from the PMOS region. A stress is transferred from the SMT layer into an N-channel of the NMOS transistor. The SMT layer is removed from the NMOS region, while leaving the SMT layer in the non-silicide region intact. A self-aligned silicidation (SAC) process is performed to form a salicide layer in the NMOS region and the PMOS region.

According to some embodiments, the SMT layer remained in the non-silicide region function acts as a salicide blocking (SAB) layer during the SAC process.

According to some embodiments, the SMT layer comprises a silicon oxide layer and a silicon nitride layer.

According to some embodiments, the stress comprises a tensile stress.

According to some embodiments, the stress is transferred by performing a laser spike anneal.

According to some embodiments, the method further comprises: performing a source/drain anneal to activate dopants in a source/drain region of the NMOS transistor and the PMOS transistor.

According to some embodiments, the source/drain anneal comprises a rapid thermal anneal (RTA).

According to some embodiments, before performing the SAC process, the method further comprises: shrinking spacers of the NMOS transistor and the PMOS transistor.

According to another aspect of the invention, a method for forming a semiconductor device is disclosed. A semiconductor substrate having thereon an NMOS region, a PMOS region, and a non-silicide region is provided. An NMOS transistor is formed within the NMOS region and a PMOS transistor is formed within the PMOS region. The NMOS transistor comprises N-type source/drain doped regions in the semiconductor substrate, an N-channel between the N-type source/drain doped regions, an NMOS gate over the N-channel, and first spacers on sidewalls of the NMOS gate. The PMOS transistor comprises P-type source/drain doped regions in the semiconductor substrate, a P-channel between the P-type source/drain doped regions, a PMOS gate over the P-channel, and second spacers on sidewalls of the PMOS gate.

A stress memorization technique (SMT) layer covering the NMOS region, the PMOS region, and the non-silicide region, wherein the SMT layer comprises a silicon oxide layer and a silicon nitride layer is formed. The silicon nitride layer of the SMT layer is removed from the PMOS region. A stress is transferred from the SMT layer into the N-channel of the NMOS transistor. The silicon nitride layer of the SMT layer is removed from the NMOS region, while leaving the SMT layer in the non-silicide region intact. The silicon oxide layer is removed from the NMOS region and the PMOS region to expose the N-type source/drain doped regions and the P-type source/drain doped regions. A self-aligned silicidation (SAC) process is performed to form a salicide layer on the N-type source/drain doped regions and the P-type source/drain doped regions.

According to some embodiments, the SMT layer remained in the non-silicide region function acts as a salicide blocking (SAB) layer during the SAC process.

According to some embodiments, the stress comprises a tensile stress.

According to some embodiments, the stress is transferred by performing a laser spike anneal.

According to some embodiments, the method further comprising: performing a source/drain anneal to activate dopants in the N-type source/drain doped regions and the P-type source/drain doped regions.

According to some embodiments, the source/drain anneal comprises a rapid thermal anneal (RTA).

According to some embodiments, before performing the SAC process, the method further comprises: shrinking the first spacers of the NMOS transistor and the second spacers of the PMOS transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 6 are schematic cross-sectional views of a method of manufacturing a semiconductor device according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized and structural, logical, and electrical changes may be made without departing from the scope of the present invention. Therefore, the following detailed description is not to be considered as limiting, but the embodiments included herein are defined by the scope of the accompanying claims.

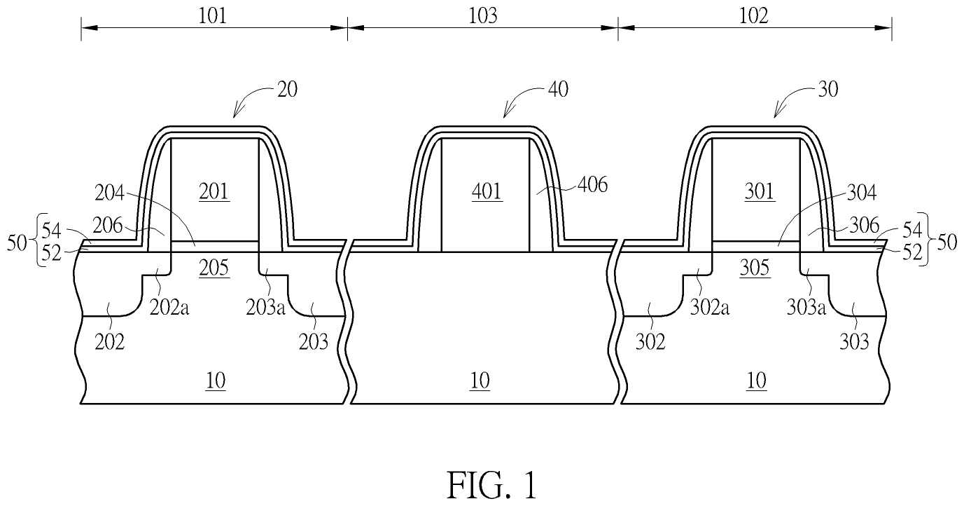

Please refer to FIGS. 1 to 6, which are schematic cross-sectional views of a method of manufacturing a semiconductor device according to an embodiment of the present invention. As shown in FIG. 1, first, a semiconductor substrate 10, such as a silicon substrate, is provided, but it is not limited thereto. According to an embodiment of the present invention, the semiconductor substrate 10 may include a fin structure, but is not limited thereto. The semiconductor substrate 10 comprises an NMOS region 101, a PMOS region 102, and a non-silicide region 103. Next, an NMOS transistor 20 and a PMOS transistor 30 are formed in the NMOS region 101 and the PMOS region 102, respectively. According to an embodiment of the present invention, the NMOS transistor 20 and the PMOS transistor 30 may be FinFETs, but are not limited thereto.

According to an embodiment of the present invention, the NMOS transistor 20 may include N-type source/drain doped regions 202 and 203 in the semiconductor substrate 10, an N-channel 205 between the N-type source/drain doped regions 202 and 203, an NMOS gate 201 on the N-channel 205, and a first spacer 206, such as a silicon nitride spacer, on the sidewall of the NMOS gate 201. In addition, there may be a gate dielectric layer 204 between the NMOS gate 201 and the N-channel 205, for example, a silicon dioxide layer.

According to an embodiment of the present invention, the N-type source/drain doped region 202 may include an N-type lightly doped drain (NLDD) region 202a, and the N-type source/drain doped region 203 may include an N-type lightly doped drain (NLDD) region 203a. The N-type channel 205 is located between the NLDD region 202a and the NLDD region 203a.

According to an embodiment of the present invention, the PMOS transistor 30 may include P-type source/drain doped regions 302 and 303 in the semiconductor substrate 10, a P-channel 305 between the P-type source/drain doped regions 302 and 303, a PMOS gate 301 on the P-channel 305, and a second spacer 306, for example, a silicon nitride spacer, on the sidewall of the PMOS gate 301. In addition, there may be a gate dielectric layer 304 between the PMOS gate 301 and the P-channel 305, for example, a silicon dioxide layer.

According to an embodiment of the present invention, the P-type source/drain doped region 302 may include a P-type lightly doped drain (PLDD) region 302a, and the P-type source/drain doped region 303 may include a P-type lightly doped drain region 303a. The P-channel 305 is located between the PLDD region 302a and the PLDD region 303a.

According to an embodiment of the present invention, at least one semiconductor structure 40, such as a resistor, a capacitor, or a diode, can be formed in the non-silicide region 103, but it is not limited thereto. According to an embodiment of the present invention, for example, the semiconductor structure 40 may include an electrode 401 and a third spacer 406 disposed on the sidewall of the electrode 401.

Next, a stress memorization technique (SMT) layer 50 is formed to cover the NMOS region 101, the PMOS region 102 and the non-silicide region 103. According to an embodiment of the present invention, the SMT layer 50 conformally covers the NMOS transistor 20, the PMOS transistor 30 and the semiconductor structure 40. According to an embodiment of the present invention, the SMT layer 50 may include a silicon oxide layer 52 and a silicon nitride layer 54. According to an embodiment of the present invention, the silicon oxide layer 52 may serve as a buffer layer, and the silicon nitride layer 54 may have a tensile stress.

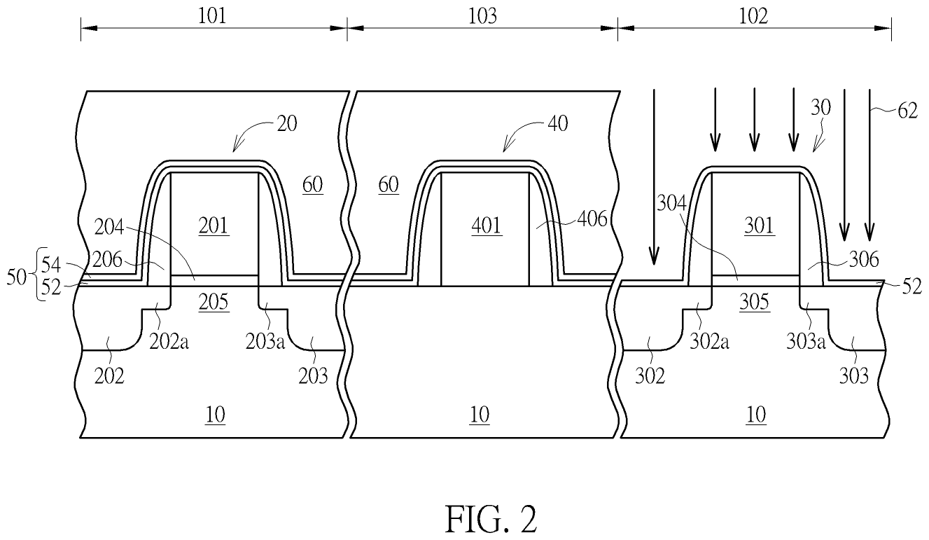

As shown in FIG. 2, the SMT layer 50 is then removed from the PMOS region 102. More specifically, the silicon nitride layer 54 of the SMT layer 50 is removed from the PMOS region 102. For example, a photoresist pattern 60 is formed on the semiconductor substrate 10 using lithographic processes such as exposure and development. The photoresist pattern 60 covers the NMOS region 101 and the non-silicide region 103 to expose the PMOS region 102. Next, an etching process 62 is performed to remove the exposed silicon nitride layer 54 of the SMT layer 50 from the PMOS region 102. Subsequently, the remaining photoresist pattern 60 is removed. According to an embodiment of the present invention, a source/drain anneal process can then be performed to activate the dopants in the N-type source/drain doped regions 202 and 203 and the P-type source/drain doped region 302 and 303. According to an embodiment of the present invention, the source/drain annealing process includes a rapid thermal anneal (RTA) process.

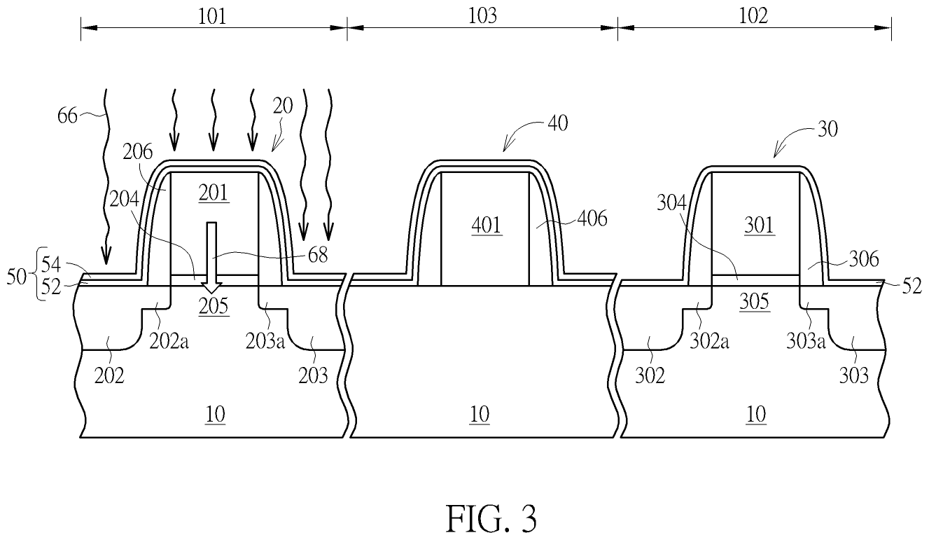

As shown in FIG. 3, a laser spike anneal process 66 is then performed to transfer a stress 68 from the SMT layer 50 to the N-channel 205 of the NMOS transistor 20. According to an embodiment of the present invention, the stress 68 includes a tensile stress.

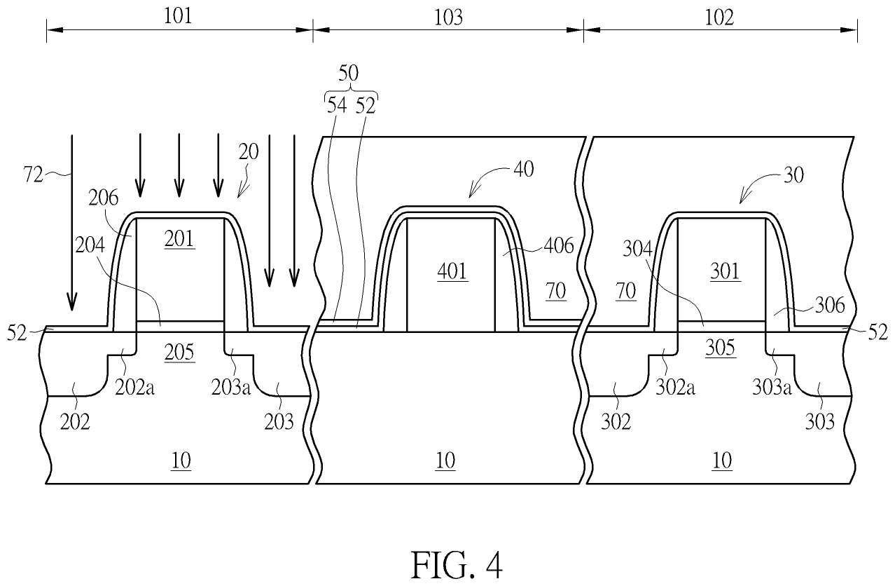

As shown in FIG. 4, the SMT layer 50 is then removed from the NMOS region 101, but the SMT layer 50 in the non-silicide region 102 is left intact. For example, a photoresist pattern 70 is formed on the semiconductor substrate 10 through processes such as exposure and development. The photoresist pattern 70 covers the PMOS region 102 and the non-silicide region 103 to expose the NMOS region 101. Then, an etching process 72 is performed to remove the exposed silicon nitride layer 54 of the SMT layer 50 from the NMOS region 101. Subsequently, the remaining photoresist pattern 70 is removed.

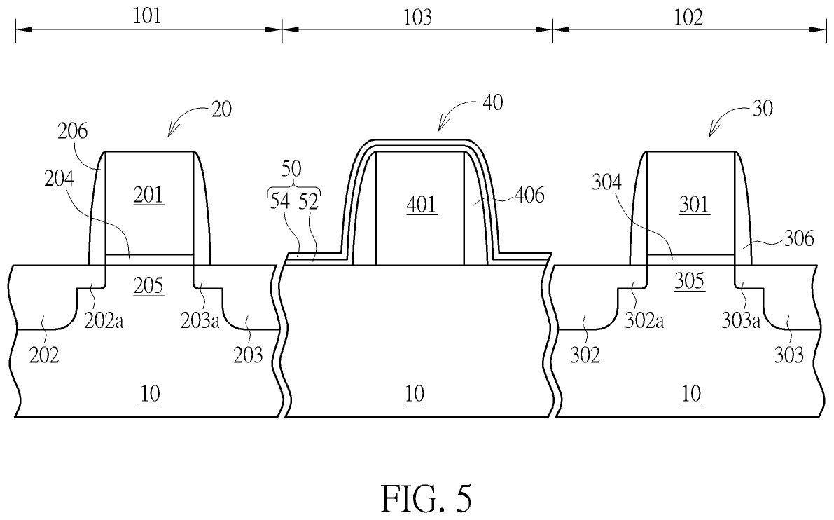

As shown in FIG. 5, the silicon oxide layer 52 is then removed from the NMOS region 101 and the PMOS region 102, revealing the N-type source/drain doped regions 202, 203 and the P-type source/drain doped region 302, 303. According to an embodiment of the present invention, at this point, the non-silicide region 103 is still covered by the SMT layer 50.

Next, a thickness reduction process may be performed on the first spacer 206 of the NMOS transistor 20 and the second spacer 306 of the PMOS transistor 30 by using, for example, dry etching or wet etching. At this point, since the non-silicide region 103 is still covered by the SMT layer 50, the thickness of the third spacer 406 of the semiconductor structure 40 will not change. In other words, after the thickness reduction process described above, the thickness of the third spacer 406 of the semiconductor structure 40 may be greater than the thickness of the first spacer 206 and the second spacer 306.

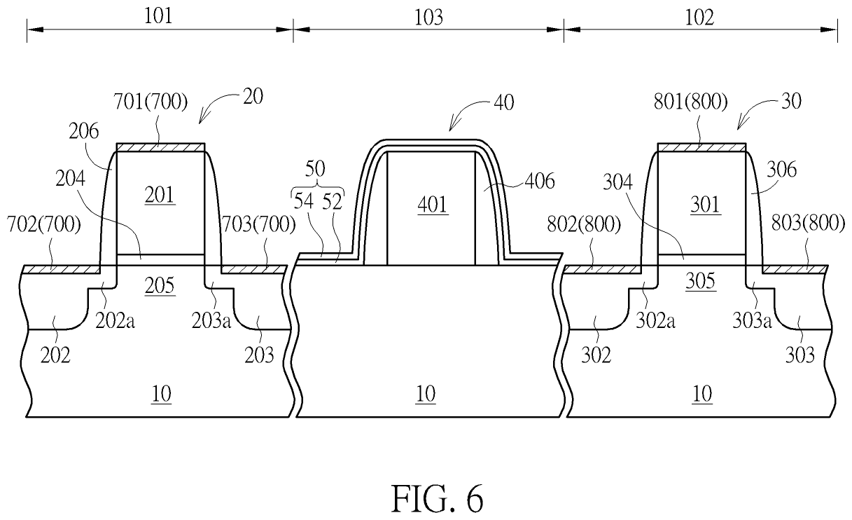

As shown in FIG. 6, a self-aligned silicidation (SAC) process is performed to form metal silicide layers 700 and 800 on the NMOS region 101 and the PMOS region 102, including, metal silicide layers 702 and 703 respectively formed on the N-type source/drain doped regions 202 and 203, metal silicide layers 802 and 803 respectively formed on the P-type source/drain doped regions 302 and 303, and metal silicide layers 701 and 801 respectively formed on the NMOS gate 201 and the PMOS gate 301. For example, a metal layer (not shown) is first blanket deposited. The metal layer is then subjected to heat treatment to react with the exposed silicon surface to form a silicide metal layer. Finally, the unreacted metal layer is removed.

According to an embodiment of the present invention, the metal silicide layers 700 and 800 may include nickel silicide (NiSi) or cobalt silicide (CoSi), but are not limited thereto. According to an embodiment of the present invention, during the SAC process, the SMT layer 50 left in the non-silicide region 103 is used as a salicide blocking (SAB) layer.

One advantage of the present invention is that the SMT layer 50 in the SMT process is also defined as the SAB layer located in the non-silicide region 103, so that the non-silicide region 103 can be covered during the subsequent self-aligned silicidation process such that a metal silicide layer will not be formed in the non-silicide region 103. Therefore, there is no need to deposit a salicide blocking layer, and the steps of etching, exposure, and development are also skipped, so that the process steps can be simplified.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a semiconductor device, comprising:
providing a semiconductor substrate having thereon an NMOS region, a PMOS region, and a non-silicide region;
forming an NMOS transistor within the NMOS region and a PMOS transistor within the PMOS region;
forming a stress memorization technique (SMT) layer covering the NMOS region, the PMOS region, and the non-silicide region;
removing the SMT layer from the PMOS region;
transferring a stress from the SMT layer into an N-channel of the NMOS transistor;
removing the SMT layer from the NMOS region, while leaving the SMT layer in the non-silicide region intact; and
performing a self-aligned silicidation (SAC) process to form a salicide layer in the NMOS region and the PMOS region.

2. The method according to claim 1, wherein the SMT layer remained in the non-silicide region function acts as a salicide blocking (SAB) layer during the SAC process.

3. The method according to claim 1, wherein the SMT layer comprises a silicon oxide layer and a silicon nitride layer.

4. The method according to claim 1, wherein the stress comprises a tensile stress.

5. The method according to claim 1, wherein said transferring the stress comprises performing a laser spike anneal.

6. The method according to claim 1 further comprising:
performing a source/drain anneal to activate dopants in a source/drain region of the NMOS transistor and the PMOS transistor.

7. The method according to claim 6, wherein the source/drain anneal comprises a rapid thermal anneal (RTA).

8. The method according to claim 1, wherein before performing the SAC process, the method further comprises:
shrinking spacers of the NMOS transistor and the PMOS transistor.

9. A method for forming a semiconductor device, comprising:
providing a semiconductor substrate having thereon an NMOS region, a PMOS region, and a non-silicide region;
forming an NMOS transistor within the NMOS region and a PMOS transistor within the PMOS region, wherein the NMOS transistor comprises N-type source/drain doped regions in the semiconductor substrate, an N-channel between the N-type source/drain doped regions, an NMOS gate over the N-channel, and first spacers on sidewalls of the NMOS gate, wherein the PMOS transistor comprises P-type source/drain doped regions in the semiconductor substrate, a P-channel between the P-type source/drain doped regions, a PMOS gate over the P-channel, and second spacers on sidewalls of the PMOS gate;
forming a stress memorization technique (SMT) layer covering the NMOS region, the PMOS region, and the non-silicide region, wherein the SMT layer comprises a silicon oxide layer and a silicon nitride layer;
removing the silicon nitride layer of the SMT layer from the PMOS region;
transferring a stress from the SMT layer into the N-channel of the NMOS transistor;
removing the silicon nitride layer of the SMT layer from the NMOS region, while leaving the SMT layer in the non-silicide region intact;
removing the silicon oxide layer from the NMOS region and the PMOS region to expose the N-type source/drain doped regions and the P-type source/drain doped regions; and
performing a self-aligned silicidation (SAC) process to form a salicide layer on the N-type source/drain doped regions and the P-type source/drain doped regions.

10. The method according to claim 9, wherein the SMT layer remained in the non-silicide region function acts as a salicide blocking (SAB) layer during the SAC process.

11. The method according to claim 9, wherein the stress comprises a tensile stress.

12. The method according to claim 9, wherein said transferring the stress comprises performing a laser spike anneal.

13. The method according to claim 9 further comprising:
performing a source/drain anneal to activate dopants in the N-type source/drain doped regions and the P-type source/drain doped regions.

14. The method according to claim 13, wherein the source/drain anneal comprises a rapid thermal anneal (RTA).

15. The method according to claim 9, wherein before performing the SAC process, the method further comprises:
shrinking the first spacers of the NMOS transistor and the second spacers of the PMOS transistor.
